(19) United States
(12) Patent Application Publication
(10) Pub. No.: US 2023/0402499 A1
(43) Pub. Date: Dec. 14, 2023

(54) HIGH DENSITY METAL LAYERS IN ELECTRODE STACKS FOR TRANSITION METAL OXIDE DIELECTRIC CAPACITORS

(71) Applicant: Intel Corporation, Santa Clara, CA (US)

(72) Inventors: Thomas Sounart, Chandler, AZ (US); Kaan Oguz, Portland, OR (US); Neelam Prabhu Gaunkar, Chandler, AZ (US); Tristan Tronic, Aloha, OR (US)

(73) Assignee: Intel Corporation, Santa Clara, CA (US)

(21) Appl. No.: 17/835,854

(22) Filed: Jun. 8, 2022

(51) Int. Cl. H01L 49/02; H01G 4/10; H01G 4/33; H01G 4/008

(52) U.S. Cl. CPC H01L 28/65; H01G 4/10; H01G 4/33; H01G 4/008

(57) ABSTRACT

Capacitors for decoupling, power delivery, integrated circuits, related systems, and methods of fabrication are disclosed. Such capacitors include a transition metal oxide dielectric between two electrodes, at least one of which includes a conductive metal oxide layer on the transition metal oxide dielectric and a high density metal layer on the conductive metal oxide.

### BACKGROUND

Decoupling capacitors are used to supply current to processor die during transient spikes in power demand and to minimize power supply noise. Power delivery requirements for processors such as server processors include an increasing demand for more decoupling capacitance on or close to the die to prevent excessive voltage droop on critical voltage rails such as the V_{cc,in} and V_{cc,out}, the voltage regulator input and output, respectively. For a given geometry, capacitance scales on the dielectric permittivity, so incorporating dielectric materials with the highest possible relative permittivity (k) is desirable to increase decoupling capacitance density, including in metal-insulator-metal devices on die, in the package, or on interposer die or chiplets. However, deployment of some high relative permittivity materials cause difficulties inclusive of excessive leakage current.

Furthermore, the previously discussed operational voltages, such as V_{cc,in}, may have a standard operational voltage of 1.8 V, but power delivery efficiency can be improved substantially by increasing this voltage to 3 V or even further to 5 V or more. Current decoupling capacitors cannot operate at greater than 2 V. It is desirable to provide decoupling capacitors that are capable of operating at higher operation voltages and low leakage current. It is with respect to these and other considerations that the present improvements have been needed. Such improvements may become critical as the desire to implement decoupling capacitors becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an illustration of a cross-sectional side view of a semiconductor package including a thin film capacitor in a portion thereof;

FIG. 2 is an illustration of a cross-sectional view of a thin film capacitor structure including a multilayer capacitor material stack;

FIG. 3A is an illustration of a cross-sectional view of a thin film capacitor structure including an alternative multilayer capacitor material stack;

FIG. 3B is an illustration of a cross-sectional view of a thin film capacitor structure including another alternative multilayer capacitor material stack;

FIG. 4 is an illustration of a system employing one or more capacitors having a material stack with a transition metal oxide dielectric layer and at least one electrode having a conducting noble metal oxide on the transition metal oxide dielectric layer and a high density metal layer on the conducting noble metal oxide;

FIG. 5 is a flow diagram illustrating methods for forming capacitor structures;

FIGS. 6A, 6B, 6C, 6D, 6E, 6F, and 6G are cross-sectional views of exemplary capacitor structures as selected fabrication operations in the methods of FIG. 5 are performed;

FIGS. 7A, 7B, 7C, 7D, 7E, 7F, 7G, 7H, and 7I are cross-sectional views of exemplary capacitor structures as selected fabrication operations in the methods of FIG. 5 are performed;

FIG. 8 is an illustration of an example multi-layer capacitor circuit;

FIG. 9 is an illustration of a cross-sectional side view of a packaged system;

FIG. 10 is an illustrative diagram of a mobile computing platform employing a device having a capacitor; and

FIG. 11 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The term “predominantly” indicates the predominant constituent is the constituent of greatest proportion in the layer or material. For example, a material including predominantly a particular constituent is not less than 51% of the particular constituent. The term “substantially pure” indicates a material of not less than 95% of the particular constituent. The term “nearly pure” indicates a material of not less than 99% of the particular constituent and the term “pure” indicates a material of not less than 99.9% of the particular constituent. Such material percentages are given based on weight percentage unless otherwise indicated.

Capacitor structures, device structures, apparatuses, integrated circuits, computing platforms, and methods are described herein related to capacitors having one or both electrodes including a conductive noble metal oxide and a high density metal layer on the conductive noble metal oxide.

As described above, it may be advantageous to provide low leakage capacitors such as thin film capacitors that are capable of operating at higher operational voltages such as voltages of 3 V, 5 V, or more. In some embodiments, a capacitor includes a dielectric layer between first and second electrodes such that the dielectric layer is a transition metal oxide (i.e., includes a transition metal and oxygen) and one or both of the first and second electrodes includes a noble metal oxide (i.e., includes a noble metal and oxygen) on the transition metal oxide and a high density metal on the noble metal oxide. As used herein, the term noble metal indicates those metals that are resistive to corrosion and oxidation and includes at least the following: ruthenium, rhodium, palladium, silver, osmium, iridium, platinum, and gold. In some embodiments, both the first and second electrodes includes a noble metal oxide such that the noble metal may be the same or different between the two electrodes. In some embodiments, only one of the first and second electrodes includes a noble metal oxide. In some such embodiments, the other electrode may include a high density metal, which may advantageously have a high work function, on the transition metal oxide. As used herein, the term high density metal indicates a conductive material having a density of not less than 16 g/cc.

Notably, the present capacitors incorporate a high density metal layer (i.e., ρ>16 g/cc), such as tungsten (W) into the capacitor electrode stack. The high density metal layer provides an oxygen barrier layer to reduce oxygen diffusion out of the transition metal oxide dielectric, thus reducing oxygen vacancy defects and enabling low-leakage capacitors. For example, such oxygen diffusion may occur during thermal processing at elevated temperatures. Such processing occurs as part of die attach, packaging, back end line processing, and others. In some embodiments, the transition metal oxide is titanium oxide (i.e., includes titanium and oxygen), TiO₂. For example, titanium oxide (inclusive of titanium dioxide (TiO₂)) is a paraelectric dielectric that has a higher relative permittivity (40-150) relative to other high-k dielectrics even with low temperature deposition in an amorphous or nanocrystalline state. However, oxygen vacancy defects generated from thermal processing during subsequent processing (e.g., package assembly, such as reflow at about 250° C., or other downstream processing) can cause excessive leakage current. The structures and techniques discussed herein advantageously employ electrodes having a conductive noble metal oxide on the transition metal oxide dielectric, and a high density metal on the conductive noble metal oxide to reduce or eliminate such oxygen vacancy formation and achieve high permittivity capacitors with low leakage. An electrode absent conductive noble metal oxide can have a high density metal on the transition metal oxide dielectric.

Although use of titanium oxide may be advantageous, the electrode system discussed herein may be used to reduce oxygen vacancy defects in any high-k transition metal oxide (TMO) dielectric, such as hafnium oxide (HfO₂), aluminum oxide (Al₂O₃), and hafnium zirconium oxide (HfₓZr₁₋ₓO; HZO). The structures and techniques discussed herein improve electrical performance of any such oxide dielectric capacitors for power delivery, memory, or other applications. Such structures and techniques may advantageously enable higher input voltage, which is of increasing performance due to routing loss scaling. For example, standard V_{cc,in} operational voltage is currently 1.8 V, but power delivery efficiency may be improved substantially by increasing this voltage to 3 V or even 5 V or more, which is enabled using the disclosed capacitor structures.

The capacitor structures discussed herein may be characterized as thin film capacitors and such capacitors may allow higher voltage power delivery in a variety of contexts including system on a chip (SOC) applications. Efficiencies from higher voltage power delivery may be combined with other technologies (e.g., fully integrated voltage regulators, coaxial magnetic integrated inductors, etc.) for overall improved system efficiency and performance.

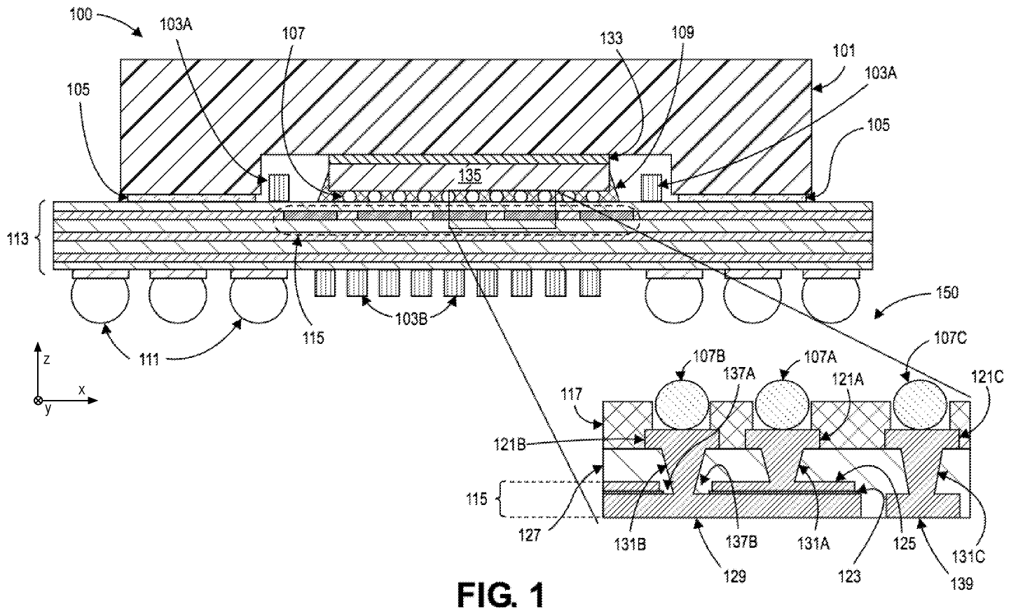

FIG. 1 is an illustration of a cross-sectional side view of a semiconductor package 100 including a thin film capacitor 115 in a portion 150 thereof, arranged in accordance with at least some implementations of the present disclosure. Portion 150 may also be referred to as an electronic package portion 150. FIG. 1 also provides an enlarged illustration of electronic package portion 150.

Semiconductor package 100 includes a package substrate 113, a component 135, a heat spreader 101, and other components, as discussed below. In some embodiments, package substrate 113 includes alternating layers of dielectric material (e.g., build-up layers) and metal layers, and a solder resist layer may be positioned on a topmost or a bottommost layer of package substrate 113. Package substrate 113 may be a cored or coreless package substrate. In some embodiments, electronic package portion 150 is integrated as part of package substrate 113. Component 135 is electrically coupled to the package substrate 113. Component 135 may be or include any suitable electronic device or devices. In some embodiments, component 135 is an integrated circuit die, a die stack, a dedicated capacitor die, or the like. In some embodiments, component 135 is electrically coupled to package substrate 113 by interconnects 107 (including interconnects 107A, 107B, 107C). In some embodiments, an underfill 109 encapsulates interconnects 107 and is between a bottom surface of component 135 and a top surface of package substrate 113. Semiconductor package 100 may also include interconnects 111 on a bottom side of package substrate 113, and interconnects 111 may be bumps, pillars, or the like formed from solder, copper, lead, any other suitable metal or alloy, or any combination thereof. Thin film capacitor 115 may be fabricated on or in component 135 (e.g., a silicon integrated circuit die), integrated into build up layers or a glass core in package substrate, or the like. In the illustrated example, thin film capacitor 115 is integrated into build up layers of package substrate 113, however thin film capacitor 115 may be incorporated into any component of semiconductor package 100. For example, capacitor 115 may be fabricated in redistribution layers (RDLs) including fan-out wafer level packaging (FOWLP) or fan-out panel level packaging (FOPLP), or in back end of the line (BEOL) layers on-die, or in any geometry including trench and via capacitors.

In some embodiments, semiconductor package 100 includes one or more die side multilayer ceramic capacitors 103A (MLCCs) or one or more landside multilayer ceramic capacitors 103B to provide capacitance for component 135. As shown, MLCCs 103A may be adjacent to a heat spreader 101 and component 135 landside multilayer ceramic capacitors 103B may be positioned on a bottom side of package substrate 113. In some embodiments, semiconductor package 100 may also include one or more on-die metal-insulator-metal (MIM) capacitors (not shown), for example, in component 135 to provide capacitance for component 135. In some embodiments, the materials discussed with respect to thin film capacitor 115 may be deployed in such MIM capacitors.

As discussed, semiconductor package 100 may also include heat spreader 101, which spreads thermal energy from component 135 to a larger area and, optionally to a heat sink positioned over and thermally coupled to heat spreader 101 via a thermal interface material. As shown in FIG. 1, heat spreader 101 may be coupled to package substrate 113 and component 135 using an adhesive 105 and a thermal interface material 133, respectively.

In some embodiments, for improved performance of semiconductor package 100, at least one thin film capacitor 115 may be positioned in package substrate 113. As used herein, the term in indicates thin film capacitor 115 is fully or at least partially embedded in package substrate 113. Notably, at least a portion of thin film capacitor 115 may be exposed from package substrate 113. Thin film capacitor 115 provides a decoupling capacitance for semiconductor package 100. For example, thin film capacitor 115 may provide a decoupling capacitance to component 135. In some embodiments, thin film capacitor 115 is formed as part of the package substrate 113 such that thin film capacitor 115 is formed using the manufacturing operations and processes used to form package substrate 113. Thin film capacitor 115 may be positioned anywhere in package substrate 113. In some embodiments, thin film capacitor 115 is positioned in package substrate 113 to span an area of the package substrate 113 under the component 135. In some embodiments, thin film capacitor 115 is located in or on a layer of package substrate 113 under component 135 such that an area (i.e., in the x-y plane) of thin film capacitor 115 at least partially overlaps an area (i.e., in the x-y plane) of component 135.

As discussed, thin film capacitor 115 may be embedded in a layer of package substrate 113. In some embodiments, thin film capacitor 115 is positioned in a topmost layer of the package substrate 113. In some embodiments, thin film capacitor 115 is positioned in a bottommost layer of the package substrate 113. In some embodiments, thin film capacitor 115 is positioned in a middle layer of the package substrate 113. In some embodiments, multiple thin film capacitors 115 are employed in the same or different layers of package substrate 113.

As shown, electronic package portion 150 includes thin film capacitor 115, which includes a bottom electrode or conductor 129, a multilayer capacitor material stack 123 on or over bottom conductor 129, and a top electrode or conductor 125 on or over multilayer capacitor material stack 123. Herein the term electrode indicates a conductive material through which electricity enters or exits a device or a device portion. Notably, thin film capacitor 115 may include top and bottom (or first and second) electrodes and, each of the top and bottom (or first and second) may include multiple electrodes or electrode layers. For example, as discussed further herein, multilayer capacitor material stack 123 includes a dielectric layer between top and bottom (or first and second) electrodes or electrode layers. The bottom electrode of multilayer capacitor material stack 123 is on or over bottom conductor 129 and top conductor 125 is on or over the top electrode of multilayer capacitor material stack 123.

In some embodiments, each of top conductor 125 and bottom conductor 129 are formed from a conductive material (e.g., a metal, a metal alloy, etc.). Top conductor 125 and bottom conductor 129 may be formed of the same materials or they may be different. In some embodiments, top conductor 125 is a V_{CC} electrode or rail and the bottom conductor 129 is a V_{SS} electrode or rail. In some embodiments, bottom conductor 129 is a V_{CC} electrode or rail and the top conductor 125 is a V_{SS} electrode or rail. Multilayer capacitor material stack 123 includes a dielectric layer between electrode layers as discussed further herein. Although illustrated in FIG. 1 as a single layer for the sake of clarity of presentation, it is to be appreciated that multilayer capacitor material stack 123 includes a stack of multiple layers where at least one of the layers is a TMO dielectric material such as a high k dielectric material. Furthermore, the TMO dielectric may include multiple layers of different TMO dielectric materials. For example, the TMO dielectric layer may be a multilayer stack. Exemplary TMO dielectric multilayer stacks include a titanium oxide (TiO₂) layer and a hafnium oxide (HfO₂) layer or layers, alternating layers of titanium oxide and hafnium oxide or aluminum oxide (Al₂O₃), or any multilayer stack inclusive of the materials discussed herein. As used herein, high k dielectrics refer to dielectrics that have a k value that is greater than 10. In some embodiments, high k dielectrics include one or more of hafnium oxide, hafnium silicon oxide, lanthanum oxide, lanthanum aluminum oxide, zirconium oxide, zirconium silicon oxide, hafnium zirconium oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Notably, as discussed below, the dielectric layer of multilayer capacitor material stack 123 is advantageously titanium oxide such as a nanocrystalline or amorphous titanium oxide.

In some embodiments, electronic package portion 150 includes openings 137A, B such that opening 137A is in multilayer capacitor material stack 123 and opening 137B is in top conductor 125. Openings 137A, B may be positioned over one another and reveal a surface of bottom conductor 129. Electronic package portion 150 also includes a via 131A over top conductor 125, a via 131B through openings 137A, B that lands on bottom conductor 129, and a via 131C on a pad 139. Electronic package portion 150 may also include a pad 121A on via 131A, a pad 121B on via 131B, and a pad 121C on via 131C. Furthermore, interconnects 107A-C (e.g., bumps, pillars, etc.) are on pads 121A-C, respectively, such that interconnects 107A-C may be solder, copper, other conductive materials, or any combination thereof.

Each of top conductor 125, multilayer capacitor material stack 123, bottom conductor 129, pad 139, vias 131A-C, and openings 137A, B are positioned or embedded in a build-up layer 127, which may be formed from a build-up film. Furthermore, a solder resist layer 117 may be positioned on build-up layer 127, and solder resist layer 117 includes openings that expose surfaces of pads 121A-C such that interconnects 107A-C are positioned on the exposed surfaces of pads 121A-C. Build-up layer 127 may be the topmost or bottommost layer of package substrate 113 below the topmost or above the bottommost layer of the package substrate 113. The embodiment FIG. 1 illustrates build-up layer 127 as the topmost layer of package substrate 113 such that thin film capacitor 115 may be advantageously placed as close as possible to component 135 to provide thin film capacitor 115 a low inductance path to component 135. However, thin film capacitor 115 may be in any layer of package substrate 113.

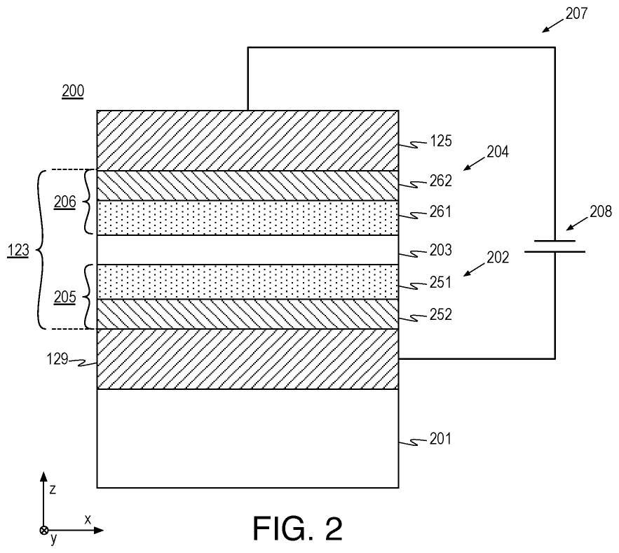

FIG. 2 is an illustration of a cross-sectional view of a thin film capacitor structure 200 including multilayer capacitor material stack 123, arranged in accordance with at least some implementations of the present disclosure. As shown, thin film capacitor structure 200 may include a substrate 201, bottom conductor 129 (or bottom electrode), a first multilayer electrode 202, a TMO dielectric layer 203, a second multilayer electrode 204, and top conductor 125 (or top electrode). As discussed, in some embodiments, multilayer capacitor material stack 123 is employed in package substrate 113. For example, substrate 201 may be a portion of package substrate 113. In other embodiments, multilayer capacitor material stack 123 is implemented on or in a motherboard, on or in an integrated circuit die, or the like.

For example, substrate 201 may be any suitable microelectronic substrate. In some embodiments, substrate 201 is a motherboard. In some embodiments, substrate 201 is a die substrate. Substrate 201 may include any suitable material and any types of devices. For example, substrate 201 may include any number and type of semiconductor devices formed within a semiconductor substrate material. In some examples, substrate 201 includes a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. Semiconductor devices within substrate 201 may include transistors (planar or non-planar), memory devices, capacitors, resistors, optoelectronic devices, switches, or any other active or passive electronic devices. In some embodiments, substrate 201 includes, ascending in the z-direction, monocrystalline silicon, an insulator layer (such as silicon dioxide having a thickness in the range of 50 to 150 nm) and a conductor layer or patterned conductor layer (such as titanium having a thickness in the range of 50 to 150 nm).

Furthermore, multilayer capacitor material stack 123, inclusive of first multilayer electrode 202, TMO dielectric layer 203, and second multilayer electrode 204 having characteristics discussed further herein below, may be employed in such contexts. Conductors 129, 125 may have any suitable thicknesses such as thicknesses (in the z-dimension) in the range of about 50 to 200 nm, 200 to 300 nm, 225 to 325 nm, or the like for applications on a component device (e.g., over a silicon substrate) or thicknesses in the range of about 5 to 25 microns for package substrate applications. Conductors 129, 125 may employ any suitable conductive materials such as copper, aluminum, or other known conductive materials.

Thin film capacitor structure 200 may be characterized as a thin film capacitor (TFC), a capacitor structure, an integrated capacitor, or, simply, a capacitor. Thin film capacitor structure 200 may be employed in any suitable circuitry such as power delivery circuitry, power supply circuitry, or other applications. Thin film capacitor structure 200 includes first multilayer electrode 202, TMO dielectric layer 203, and second multilayer electrode 204. Also as shown, first multilayer electrode 202 and second multilayer electrode 204 are coupled to a power supply circuit 207 inclusive of a power supply 208. Power supply 208 may include any suitable power supply or related components such as a batter, a power adapter, and related circuitry.

TMO dielectric layer 203 may include a material including oxygen and any suitable transition metal. In some embodiments, TMO dielectric layer 203 is a stoichiometric composition of the transition metal and oxygen. In some embodiments, TMO dielectric layer 203 is titanium oxide (i.e., including titanium and oxygen) such as amorphous or nanocrystalline titanium oxide having a crystallite size on the order of a few nanometers (e.g., 2-40 nm). For example, TMO dielectric layer 203 may be TiO₂. Such titanium oxide dielectric layers have a high k (e.g., 80-100) and may be deposited via a sputtering process. In some embodiments, TMO dielectric layer 203 is hafnium oxide (HfO₂) such that TMO dielectric layer 203 includes hafnium and oxygen. In some embodiments, TMO dielectric layer 203 is aluminum oxide (Al₂O₃) such that TMO dielectric layer 203 includes aluminum and oxygen. In some embodiments, TMO dielectric layer 203 is hafnium zirconium oxide (HfₓZr₁₋ₓO; HZO) such that TMO dielectric layer 203 includes hafnium, zirconium, and oxygen. TMO dielectric layer 203 may have any suitable thicknesses such as thicknesses (in the z-dimension) in the range of 20 to 100 nm; 30 to 50 nm; 35 to 45 nm; to 100 nm; or 80 to 100 nm. In some embodiments, TMO dielectric layer 203 has a thickness of not less than 20 nm, 40 nm, or 80 nm.

TMO dielectric layer 203 is between first multilayer electrode 202 (e.g., a bottom electrode) and second multilayer electrode 204 (e.g., a top electrode). In the example of FIG. 2, both electrodes 202, 204 are multilayer (bilayer) electrodes each with a conductive noble metal oxide layer on TMO dielectric layer 203 and a high density metal layer on the conductive noble metal oxide layer. For example, first multilayer electrode 202 includes a multilayer stack 205 of a conductive noble metal oxide layer 251 on TMO dielectric layer 203 and a high density metal layer 252 on conductive noble metal oxide layer 251. Similarly, second multilayer electrode 204 includes a multilayer stack 206 of a conductive noble metal oxide layer 261 on TMO dielectric layer 203 and a high density metal layer 262 on conductive noble metal oxide layer 251. Notably, high density metal layers 252, 262 provide an oxygen diffusion barrier to reduce oxygen diffusion out of TMO dielectric layer 203 while conductive noble metal oxide layers 251, 261 provide an oxygen source for TMO dielectric layer 203. Thereby, oxygen vacancy defects are reduced or eliminated in TMO dielectric layer 203, which enables a low leakage thin film capacitor structure 200.

Conductive noble metal oxide layers 251, 261 may have the same characteristics (i.e., materials, material compositions, thickness, etc.) or some or all of such characteristics may be different. In some embodiments, one or both of conductive noble metal oxide layers 251, 261 includes one or more of ruthenium oxide (i.e., ruthenium and oxygen), rhodium oxide (i.e., rhodium and oxygen), palladium oxide (i.e., palladium and oxygen), silver oxide (i.e., silver and oxygen), osmium oxide (i.e., osmium and oxygen), iridium oxide (i.e., iridium and oxygen), platinum oxide (i.e., platinum and oxygen), or gold oxide (i.e., gold and oxygen). As discussed further herein below, deployment of ruthenium oxide or iridium oxide may be particularly advantageous in some material systems. Conductive noble metal oxide layers 251, 261 may have any suitable thicknesses such as thicknesses (in the z-dimension) in the range of 10 to 50 nm; 15 to 30 nm; 20 to 40 nm; or 30 to 50 nm. In some embodiments, Conductive noble metal oxide layers 251, 261 have a thickness of about 20 nm.

The composition of the noble metal oxide (e.g., NMOₓ, where NM indicates any noble metal element) may be any suitable concentration. In some embodiments, the noble metal oxide is stoichiometric NMOₓ (i.e., IrO₂ in the case of iridium). In some embodiments, the noble metal oxide may be deficient in oxygen (i.e., IrO₂₋₆ in the case or iridium, where δ>0 and less than 2 but not typically less than 1). In some embodiments, the noble metal oxide includes not less than 30% oxygen. In some embodiments, the noble metal oxide includes not less than 40% oxygen. In some embodiments, the noble metal oxide includes not less than 50% oxygen. In some embodiments, the noble metal oxide includes not less than 60% oxygen. In some embodiments, the noble metal oxide includes an oxygen concentration in the range of 30 to 67% oxygen.

As shown, high density metal layer 252 of multilayer stack 205 is on conductive noble metal oxide layer 251 and high density metal layer 262 of multilayer stack 206 is on conductive noble metal oxide layer 261. High density metal layers 252, 262 provide an oxygen diffusion barrier to reduce oxygen diffusion out of TMO dielectric layer 203. High density metal layers 252, 262 may include any suitable high density metal. In some embodiments, one or both of high density metal layers 252, 262 have a density of not less than 16 g/cc; not less than 19 g/cc; not less than 20 g/cc; or not less than 22 g/cc.

High density metal layers 252, 262 may include any metal material system having such densities inclusive of alloyed materials, or substantially pure (i.e., ≥95%), nearly pure (i.e., ≥99%), or pure (i.e., ≥99%) single constituent materials. In some embodiments, one or both of high density metal layers 252, 262 are substantially pure, nearly pure, or pure tungsten. In some embodiments, one or both of high density metal layers 252, 262 are substantially pure, nearly pure, or pure iridium. In some embodiments, one or both of high density metal layers 252, 262 are substantially pure, nearly pure, or pure gold. In some embodiments, one or both of high density metal layers 252, 262 are substantially pure, nearly pure, or pure platinum. In some embodiments, one or both of high density metal layers 252, 262 are substantially pure, nearly pure, or pure osmium. In some embodiments, one or both of high density metal layers 252, 262 are substantially pure, nearly pure, or pure tantalum. High density metal layers 252, 262 may have any suitable thicknesses such as thicknesses (in the z-dimension) in the range of 5 nm to several (i.e., 3 to 5) microns; 5 to 15 nm; 10 to 20 nm; 20 to 50 nm; 30 to 60 nm; or 100 nm to 5 microns.

In some embodiments, one or both of high density metal layers 252, 262 may be a multilayer stack such as a bilayer stack of such materials. In some embodiments, one or both of high density metal layers 252, 262 includes a tungsten layer on respective conductive noble metal oxide layers 251, 261 and a second metal layer on the tungsten layer. In some embodiments, the second metal layer is advantageously palladium.

Furthermore, particular material systems may offer advantages inclusive of improved performance, manufacturability, cost, and others. In some embodiments, one of high density metal layers 252, 262 advantageously includes pure, nearly pure, or pure tungsten on one of conductive noble metal oxide layers 251, 261 and the other of high density metal layers 252, 262 incudes one of pure, nearly pure, or pure iridium or pure, nearly pure, or pure tungsten on the other of conductive noble metal oxide layers 251, 261. For example, multilayer capacitor material stack 123 may advantageously include a stack of an iridium or tungsten high density metal layer 252, a ruthenium oxide conductive noble metal oxide layer 251, a titanium oxide TMO dielectric layer 203, a ruthenium oxide conductive noble metal oxide layer 261, and a tungsten high density metal layer 262. In some embodiments, the above multilayer capacitor material stack 123 includes an iridium high density metal layer 252.

The discussed thin film capacitor structure 200 incorporates high density metal layers 252, 262 (e.g., ρ>16 g/cc) in one or both of multilayer stacks 205, 206. High density metal layers 252, 262, such as tungsten, included in multilayer capacitor material stack 123 acts as an oxygen barrier layer to reduce oxygen diffusion out of TMO dielectric layer 203 thus reducing oxygen vacancy defects and enabling low-leakage capacitors with high k dielectrics. High density metal layer 252 may also advantageously affect the deposition and structure of conductive noble metal oxide layer 251 (e.g., the NMOₓ layer) and the TMO dielectric layer 203 to increase the capacitance of the thin film capacitor structure 200 to a higher value than without high density metal layer 252. Discussion now turns to material systems where one of multilayer electrodes 202, 204 are replaced with an electrode structure absent a conductive noble metal oxide layer. In such systems, a high density metal layer is on TMO dielectric layer 203. In such embodiments, the high density metal layer may advantageously have a high work function.

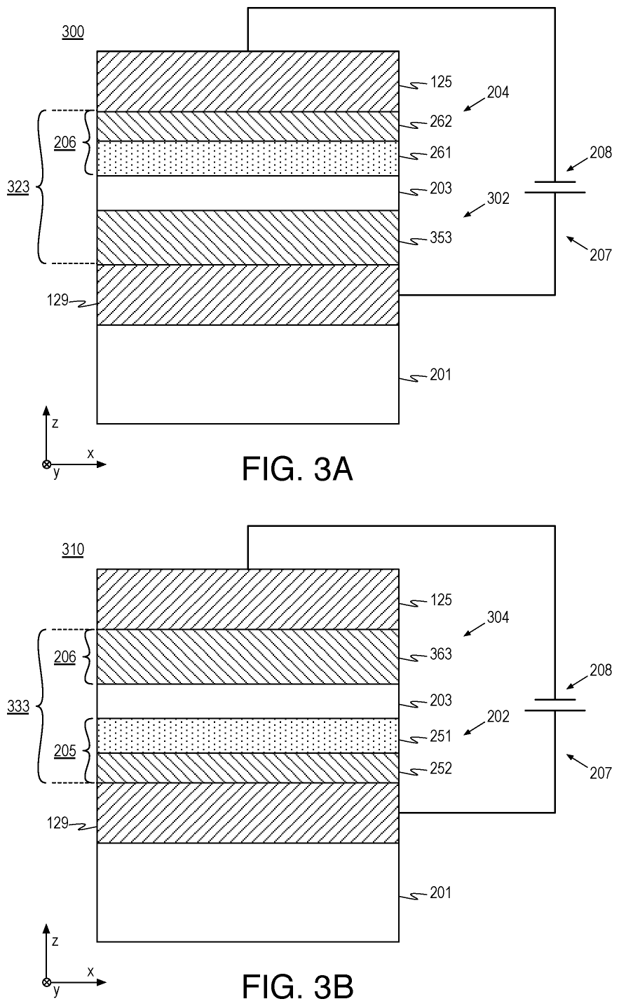

FIG. 3A is an illustration of a cross-sectional view of a thin film capacitor structure 300 including a multilayer capacitor material stack 323, arranged in accordance with at least some implementations of the present disclosure. In FIG. 3A and elsewhere herein, like numerals are used to indicate like components, which may have any characteristics discussed herein.

As shown, thin film capacitor structure 300 may include substrate 201, bottom conductor 129 (or bottom electrode), a first electrode 302, TMO dielectric layer 203, second multilayer electrode 204, and top conductor 125 (or top electrode). As discussed, multilayer capacitor material stack 323 is employed in package substrate 113, on or in a motherboard, on or in an integrated circuit die, or the like.

In the embodiment of FIG. 3A, multilayer capacitor material stack 323 includes first electrode 302 having a high density metal layer 353 on TMO dielectric layer 203. Multilayer capacitor material stack 323 may include a single high density metal layer 252 or a multilayer high density metal stack. High density metal layer 353 provides an oxygen diffusion barrier to reduce oxygen diffusion out of TMO dielectric layer 203 and it is noted a single conductive noble metal oxide layer 261 may provide a sufficient oxygen source for gettering by TMO dielectric layer 203. High density metal layer 353 may include any suitable high density metal. In some embodiments, high density metal layer 353 has a density of not less than 16 g/cc; not less than 19 g/cc; not less than 20 g/cc; or not less than 22 g/cc.

As with high density metal layers 252, 262, high density metal layer 353 may include any metal material system having such densities inclusive of alloyed materials, or substantially pure (i.e., ≥95%), nearly pure (i.e., ≥99%), or pure (i.e., ≥99%) single constituent materials. In some embodiments, high density metal layer 353 is substantially pure, nearly pure, or pure iridium. In some embodiments, high density metal layer 353 is substantially pure, nearly pure, or pure tungsten. In some embodiments, high density metal layer 353 is substantially pure, nearly pure, or pure gold. In some embodiments, high density metal layer 353 is substantially pure, nearly pure, or pure platinum. In some embodiments, high density metal layer 353 is substantially pure, nearly pure, or pure osmium. In some embodiments, high density metal layer 353 is substantially pure, nearly pure, or pure tantalum. Furthermore, it may be advantageous for high density metal layer 353 to be a high work function material due to its contact with TMO dielectric layer 203, which provides particular advantage for use of iridium, platinum, or osmium. High density metal layer 353 may have any suitable thicknesses such as thicknesses (in the z-dimension) in the range of 5 to 60 nm; 5 to 15 nm; 10 to 20 nm; 20 to 50 nm; or 30 to 60 nm. In some embodiments high density metal layer 353 may be a multilayer stack such as a bilayer stack of such materials. In some embodiments, high density metal layer 353 is includes an iridium layer on TMO dielectric layer 203 and a second metal layer on the iridium layer.

Particular material systems may offer particular advantages. In some embodiments, high density metal layer 353 is advantageously pure, nearly pure, or pure iridium, TMO dielectric layer 203 is titanium oxide, conductive noble metal oxide layer 261 is one of ruthenium oxide or iridium oxide, and high density metal layer 262 is pure, nearly pure, or pure tungsten. In some embodiments, the iridium high density metal layer 353 has a thickness in the range of 30 to 60 nm with 40 nm being particularly advantageous, the titanium oxide TMO dielectric layer 203 has a thickness in the range of 30 to 60 nm with 40 nm being particularly advantageous, the ruthenium oxide conductive noble metal oxide layer 261 has a thickness in the range of 10 to 30 nm with 20 nm being particularly advantageous, and the tungsten high density metal layer 262 has a thickness in the range of 50 to 20 nm with 10 nm being particularly advantageous. Other thicknesses may be deployed.

FIG. 3B is an illustration of a cross-sectional view of a thin film capacitor structure 310 including a multilayer capacitor material stack 333, arranged in accordance with at least some implementations of the present disclosure. As shown, thin film capacitor structure 310 may include substrate 201, bottom conductor 129 (or bottom electrode), first multilayer electrode 202, TMO dielectric layer 203, a second electrode 304, and top conductor 125 (or top electrode). As discussed, multilayer capacitor material stack 333 is employed in package substrate 113, on or in a motherboard, on or in an integrated circuit die, or the like.

In the embodiment of FIG. 3B, multilayer capacitor material stack 333 includes second electrode 304 having a high density metal layer 363 on TMO dielectric layer 203. Multilayer capacitor material stack 333 may include a single high density metal layer 363 or a multilayer high density metal stack. High density metal layer 363 provides an oxygen diffusion barrier to reduce oxygen diffusion out of TMO dielectric layer 203 while a single conductive noble metal oxide layer 251 may provide a sufficient oxygen source for gettering by TMO dielectric layer 203. High density metal layer 363 may include any suitable high density metal. In some embodiments, high density metal layer 363 has a density of not less than 16 g/cc; not less than 19 g/cc; not less than 20 g/cc; or not less than 22 g/cc.

As with other high density metal layers discussed herein, high density metal layer 363 may include any metal material system having such densities inclusive of alloyed materials, or substantially pure (i.e., ≥95%), nearly pure (i.e., ≥99%), or pure (i.e., ≥99%) single constituent materials. In some embodiments, high density metal layer 363 is one of substantially pure, nearly pure, or pure iridium, tungsten, gold, platinum, osmium, or tantalum. Furthermore, as with high density metal layer 353, it may be advantageous for high density metal layer 363 to be a high work function material due to its contact with TMO dielectric layer 203, which provides particular advantage for use of iridium, platinum, or osmium. High density metal layer 363 may have any suitable thicknesses such as thicknesses (in the z-dimension) in the range of 5 to 60 nm; 5 to 15 nm; 10 to 20 nm; 20 to 50 nm; or 30 to 60 nm. In some embodiments high density metal layer 363 may be a multilayer stack such as a bilayer stack of the previously discussed materials. In some embodiments, high density metal layer 363 is includes an iridium layer on TMO dielectric layer 203 and a second metal layer on the iridium layer.

In some embodiments, high density metal layer 363 is advantageously pure, nearly pure, or pure iridium, TMO dielectric layer 203 is titanium oxide, conductive noble metal oxide layer 251 is one of ruthenium oxide or iridium oxide, and high density metal layer 252 is pure, nearly pure, or pure tungsten. In some embodiments, the iridium high density metal layer 363 has a thickness in the range of 30 to 60 nm with 40 nm being particularly advantageous, the titanium oxide TMO dielectric layer 203 has a thickness in the range of 30 to 60 nm with 40 nm being particularly advantageous, the ruthenium oxide conductive noble metal oxide layer 251 has a thickness in the range of 10 to 30 nm with 20 nm being particularly advantageous, and the tungsten high density metal layer 252 has a thickness in the range of 50 to 20 nm with 10 nm being particularly advantageous. Other thicknesses may be deployed.

Notably, the techniques and capacitor structures discussed herein include, in the capacitor material stackup, at least one bilayer electrode composed of a high-density metal layer (e.g., ρ>16 g/cc), such as W, Ir, Au, Pt, Os, or Ta, and a conducting noble metal oxide electrode, such as RuO₂ and IrO₂, directly in contact with the TMO dielectric, which improves the stability of the oxide film, for improved leakage current even after going through high temperature processing such as ball attach reflow processing or others, which would otherwise degrade capacitor performance.

In some embodiments, the capacitors discussed herein are employed in voltage regulators such as fully integrated voltage regulators for higher efficiency power delivery. The thin film capacitors may be patterned into any geometry required for integration with other devices and they may be fabricated on a die (e.g., a silicon die), package substrate, or motherboard, or they may be into build-up layers of such devices (e.g., in build-up layers of an electronic package substrate or on any other substrate.

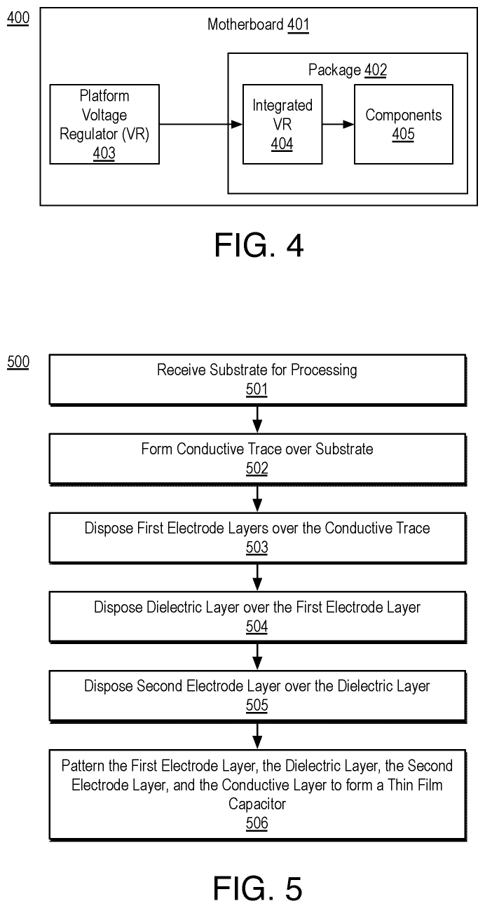

FIG. 4 is an illustration of a system 400 employing one or more capacitors having a material stack with a transition metal oxide dielectric layer and at least one electrode having a conducting noble metal oxide on the transition metal oxide dielectric layer and a high density metal layer on the conducting noble metal oxide, arranged in accordance with at least some implementations of the present disclosure. As shown, system 400 includes a motherboard 401 (or platform), a platform voltage regulator (VR) 403, and a package 402 that includes an integrated VR 404, and one or more components 405. For example, package 402 may implement semiconductor package 100 such that components 405 include one or more of components 135.

Notably, any, some, or all components of system 400 may include or employ any of thin film capacitor structures 200, 300, 310, one or more portions of thin film capacitor structures 200, 300, 310 (e.g., any of multilayer capacitor material stacks 123, 323, 333). In some embodiments, platform VR 403 provides voltage regulation for motherboard 401 and may provide a step down in voltage from, for example, 12 V to 5 V such that package 402, via integrated VR 404, receives input voltage at 5 V. In some embodiments, a thin film capacitor as discussed herein may provide a decoupling capacitor (e.g., for supply current during transient spikes in demand and to minimize noise) for platform VR 403. In a similar manner, integrated VR 404 provides voltage regulation for package 402 and may provide a step down in voltage from, for example, 5 V to 0.9 V such that one or more components 135 (e.g., integrated circuit die) receives input voltage at V. In some embodiments, a capacitor as discussed herein may provide a decoupling capacitor for integrated VR 404. In addition or in the alternative, one or more components 135 may employ a capacitor as discussed herein for internal power supply, voltage regulation, or the like.

In some embodiments, system 400 includes a power supply, a package substrate (e.g., package 402), an integrated circuit die (e.g., component 135), and a capacitor in the package substrate such that the capacitor includes TMO dielectric layer between first and second electrodes, such that one or both of the first electrode or the second electrode includes a conducting noble metal oxide on the TMO dielectric layer and a high density metal layer on the conducting noble metal oxide. The capacitor may include any characteristics discussed herein with respect to thin film capacitors, thin film capacitor structures, etc. Furthermore, in some embodiments, the capacitor is a component of a power delivery circuit (or voltage regulator circuit).

Discussion now turns to methods for forming capacitors having multilayer capacitor material stacks discussed herein.

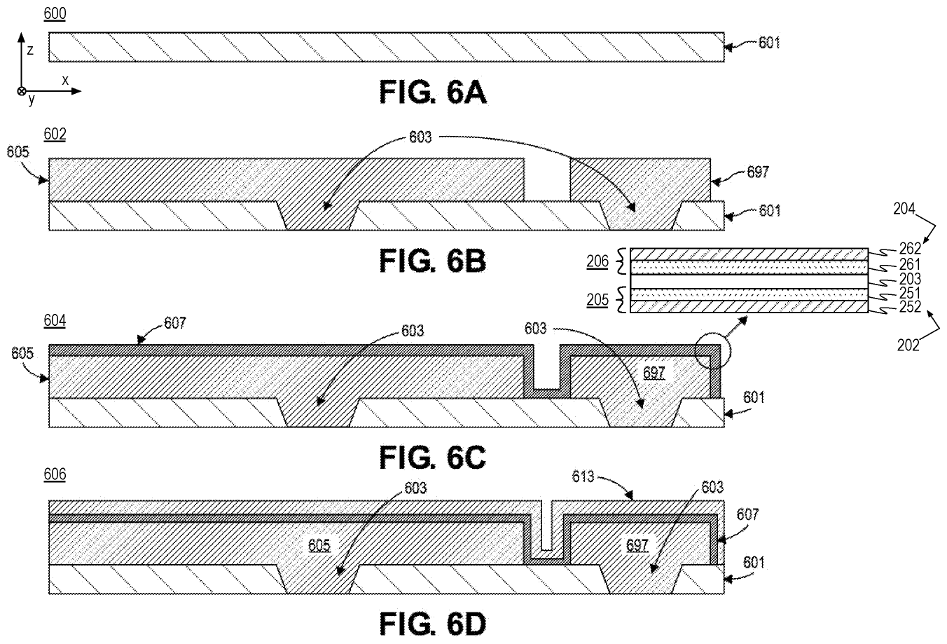

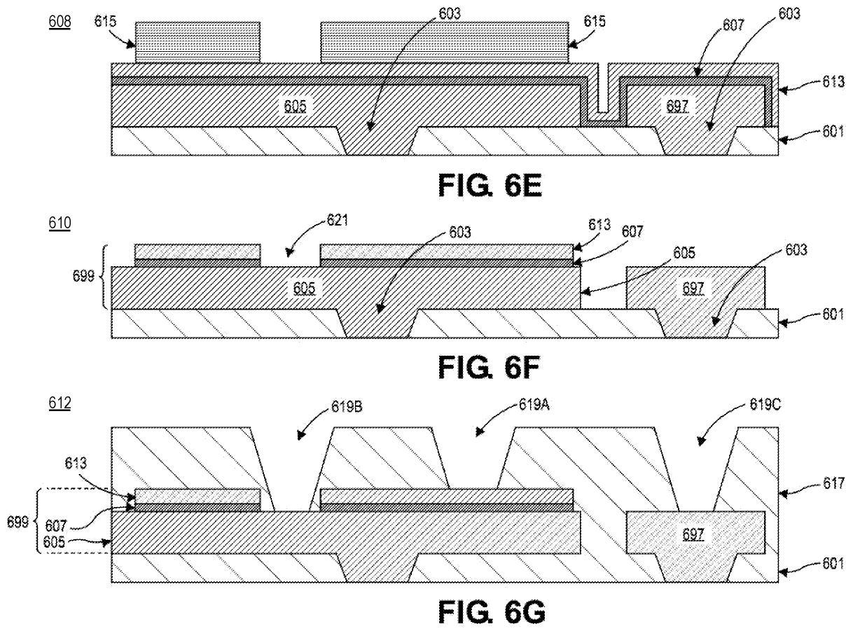

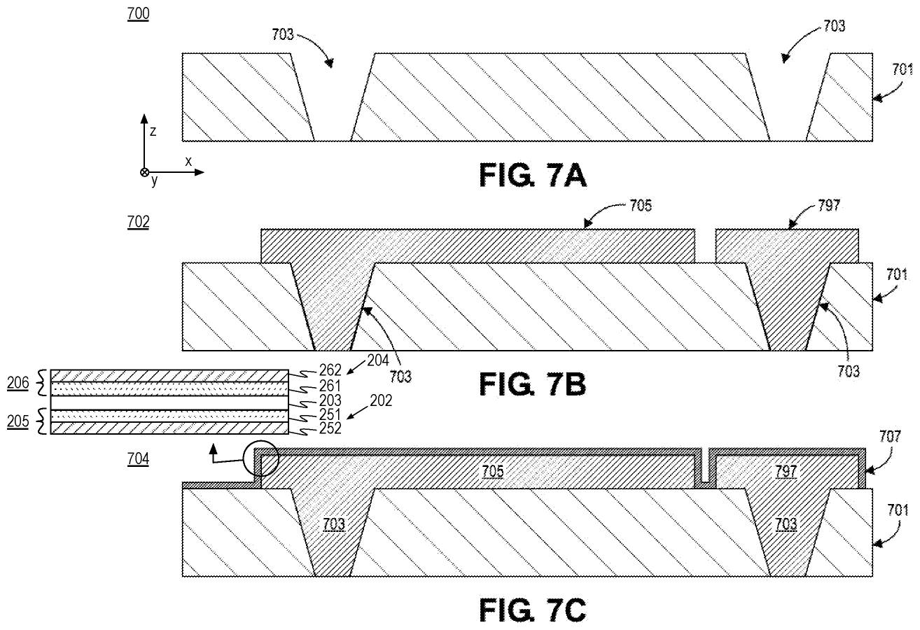

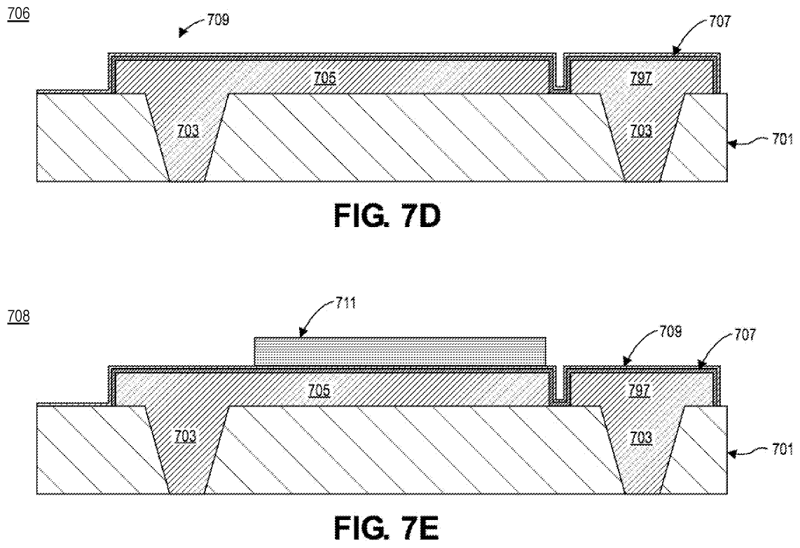

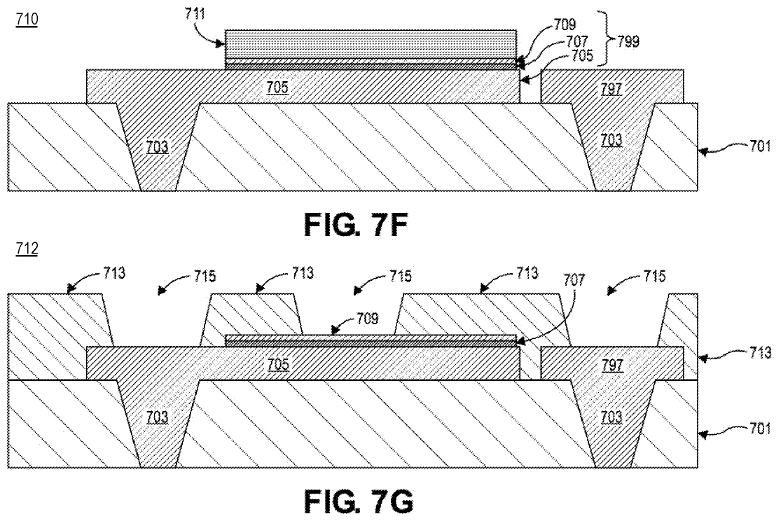

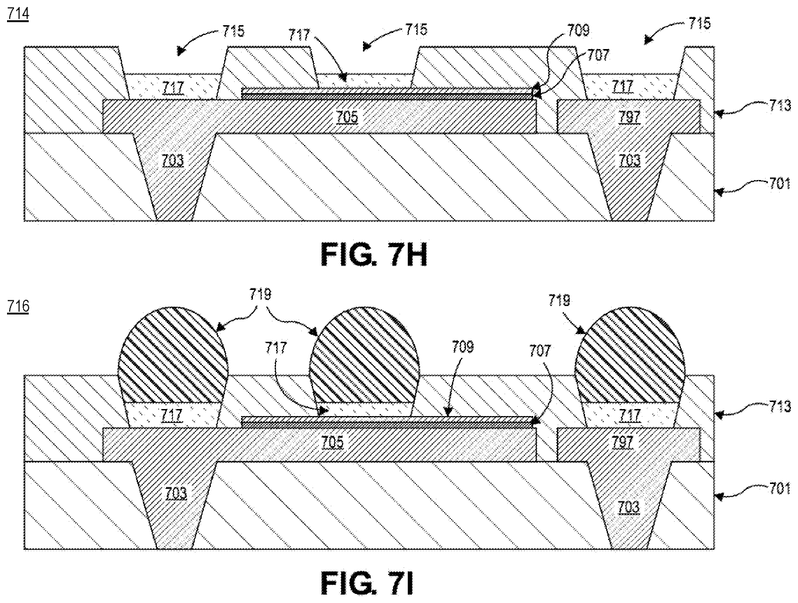

FIG. 5 is a flow diagram illustrating methods 500 for forming capacitor structures, arranged in accordance with at least some implementations of the present disclosure. For example, methods 500 may be employed to form thin film capacitor structures in in an electronic package substrate. FIGS. 6A, 6B, 6C, 6D, 6E, 6F, and 6G are cross-sectional views of exemplary capacitor structures as selected fabrication operations in methods 500 are performed, arranged in accordance with at least some implementations of the present disclosure. FIGS. 7A, 7B, 7C, 7D, 7E, 7F, 7G, 7H, and 7I are cross-sectional views of exemplary capacitor structures as selected fabrication operations in methods 500 are performed, arranged in accordance with at least some implementations of the present disclosure. For example, FIGS. 7A-7G provide a similar processing to FIGS. 6A-6G with a thinner top metal layer and less capacitor layer shown across the width. Furthermore, FIGS. 7H and 7I provide additional operations for providing interconnects for the thin film capacitor structures, which may also be applied after the thin film capacitor structure of FIG. 7G.

As shown in FIG. 5, methods 500 begin at operation 501, where a substrate (e.g., a work piece) is received for processing. The received substrate may be a partially fabricated structure that may be formed on a substrate such as a substrate board or substrate wafer. A device layer may be previously formed within, on, and/or over the substrate. The device layer may include any devices such as transistors, memory devices, capacitors, resistors, optoelectronic devices, switches, or any other active or passive electronic devices. The received substrate may further include one or more metallization layers over the device layer. In some embodiments, no metallization layers are formed over the device layer. Such devices and metallization layer(s) may be formed using any suitable technique or techniques known in the art.

Processing continues at operation 502, where a conductive layer or trace is formed over the substrate. The conductive layer trace may be formed over the substrate using any suitable technique or techniques. In some embodiments, the conductive layer trace is formed by providing a bulk layer (e.g., via electroplating) over the substrate and patterning using lithography and etch techniques. In some embodiments, the conductive layer trace is a copper layer that is a part of a metallization layer and forms a pad or electrode for a thin film capacitor.

Processing continues at operation 503, where first electrode layer(s) are formed or disposed over the conductive layer. For example, the first electrode layers may be formed as bulk conformal layers. Notably, when the first electrode is a multilayer (i.e., bilayer) stack (e.g., as discussed with respect to FIGS. 2 and 3B), operation 503 includes formation of each layer in the multilayer stack. When the first electrode is a single material layer (e.g., as discussed with respect to FIG. 3A), operation 503 includes formation of the single layer of the eventual first electrode.

The first electrode layer(s) may be formed using any suitable technique or techniques and may include any material, materials, or characteristics discussed with respect to first multilayer electrode 202 or first electrode 302. In some embodiments, the first electrode layer(s) are formed using sputtering or co-reactive sputtering techniques. In embodiments where a first electrode layer includes high density metal, sputtering or plating techniques may be employed. In embodiments where a first electrode layer includes a conductive noble metal oxide (i.e., a noble metal element and oxygen), co-reactive sputtering techniques may be employed such that a target including the noble metal is sputtered into a plasma containing oxygen. However, other techniques such as co-evaporative deposition techniques may be employed.

Processing continues at operation 504, where a TMO dielectric layer is formed over the first electrode layer. For example, the TMO dielectric layer may be formed as a bulk conformal layer. The TMO dielectric layer may be formed using any suitable technique or techniques and the resultant bulk TMO dielectric layer may include characteristics discussed with respect to TMO dielectric layer 203. In some embodiments, the TMO dielectric layer is formed using sputtering or vapor deposition techniques.

Processing continues at operation 505, where second electrode layer(s) are formed or disposed over the TMO dielectric layer. For example, the second electrode layers may be formed as bulk conformal layers. Notably, when the second electrode is a multilayer (i.e., bilayer) stack (e.g., as discussed with respect to FIGS. 2 and 3A), operation 505 includes formation of each layer in the multilayer stack. When the first electrode is a single material layer (e.g., as discussed with respect to FIG. 3B), operation 505 includes formation of the single layer of the eventual first electrode.

The second electrode layer may be formed using any suitable technique or techniques and may include any material, materials, or characteristics discussed with respect to second multilayer electrode 204 or second electrode 304. In some embodiments, the second electrode layer(s) are formed using sputtering or co-reactive sputtering techniques. In embodiments where the second electrode layers includes a noble metal oxide, co-reactive sputtering techniques may be employed as discussed with respect to operation 503.

Processing continues at operation 506, where the first electrode layer(s), the TMO dielectric layer, and the second electrode layer(s) are patterned to form a capacitor having any suitable shape and geometry. For example, the resultant capacitor may be a thin film capacitor. The discussed layers may be patterned using any suitable technique or techniques such as lithography and etch techniques. The resultant capacitor may have any characteristics discussed herein and may be formed within and/or over any substrate.

Methods 500 may further include contacting the capacitor via a second conductive layer and further providing routing (e.g., using vias and metallization layers) to the thin film capacitor. Additional routing for system circuitry may be provided by package interconnects, bonds, and so on. Thereby, the fabricated capacitor may be included in any suitable circuitry, routing, etc.

FIG. 6A illustrates an example capacitor structure 600 including a build up layer 601. For example, build up layer 601 may be a top or exposed layer of a package substrate. Although illustrated with respect to forming capacitor structures on build up layer 601 or a package substrate, as discussed, the thin film capacitor structures herein may be formed over any suitable substrate such as a silicon wafer substrate (including devices formed therein), a motherboard, a platform substrate, or the like.

FIG. 6B illustrates an example capacitor structure 602 similar to capacitor structure 600, after the formation of vias 603 in build up layer 601 and formation of a bottom electrode 605 and a pad 697. Vias 603 may be formed using any suitable technique or techniques such as drilling through build up layer 601, patterning and etch techniques, or the like. Bottom electrode 605 and pad 697 may also be formed using any suitable technique or techniques such as depositing a metal layer on build up layer 601 and in vias 603 and patterning the metal layer using lithography and etch techniques. In some embodiments, bottom electrode 605 and pad 697 are formed using semi-additive processing.

FIG. 6C illustrates an example capacitor structure 604 similar to capacitor structure 602, after the formation of a multilayer capacitor material stack 607. Multilayer capacitor material stack 607 may include any of multilayer capacitor material stacks 123, 323, 333, with multilayer capacitor material stack 123 being illustrated for the sake of clarity. As shown, in some embodiments, multilayer capacitor material stack 607 includes bulk material layers (i.e., not yet patterned layers) of high density metal layer 252, conductive noble metal oxide layer 251, TMO dielectric layer 203, conductive noble metal oxide layer 261, and high density metal layer 262. In some embodiments, multilayer capacitor material stack 607 includes bulk material layers of high density metal layer 353, TMO dielectric layer 203, conductive noble metal oxide layer 261, and high density metal layer 262 (refer to FIG. 3A). In some embodiments, multilayer capacitor material stack 607 includes bulk material layers of high density metal layer 252, conductive noble metal oxide layer 251, TMO dielectric layer 203, and high density metal layer 363 (refer to FIG. 3B). The layers of multilayer capacitor material stack 607 may be formed using any suitable technique or techniques inclusive of sputtering, co-reactive sputtering, plating techniques, atomic layer deposition, chemical vapor deposition, or the like.

FIG. 6D illustrates an example capacitor structure 606 similar to capacitor structure 604, after the formation of a conductive layer 613. Conductive layer 613 may include any suitable metal material for a conductive electrode or layer such as copper or the like. Conductive layer 613 may be formed using any suitable technique or techniques such as electroplating or deposition techniques.

FIG. 6E illustrates an example capacitor structure 608 similar to capacitor structure 606, after the formation of a photoresist pattern 615 over conductive layer 613. For example, a bulk photoresist material may be deposited and pattered using photolithography techniques to provide photoresist pattern 615. Although discussed with respect to photolithography techniques any patterning techniques may be employed.

FIG. 6F illustrates an example capacitor structure 610 similar to capacitor structure 608, after the patterning of conductive layer 613 and material stack 607 (inclusive of any material stack discussed with respect to FIG. 6C or elsewhere herein) to form a capacitor 699 that includes conductive layer 613 (formed into a top electrode or top electrode layer), bottom electrode 605 and remaining portions of material stack 607 such that capacitor 699 includes a TMO dielectric layer between first and second electrodes, one or both of which includes a conductive noble metal oxide on the TMO dielectric layer and a high density metal layer on the conductive noble metal oxide as discussed herein, and to form a landing surface 621. Furthermore, photoresist pattern 615 may be removed using any suitable technique or techniques such as resist ash techniques.

FIG. 6G illustrates an example capacitor structure 612 similar to capacitor structure 610, after the formation of a build up layer 617 and via openings 619A, B, C. As shown, build-up layer 617 may be positioned (e.g., laminated, etc.) on exposed surfaces of bottom electrode 605, material stack 607, conductive layer 613, build-up layer 601, and pad 697. Subsequently, via openings 619A, B, C are formed such that via opening 619A is on or over conductive layer 613 (e.g., a top electrode 613), via opening 619B is on or over bottom electrode 605, and via opening 619C is on or over the pad 697. Additional processing operations may be performed following formation of the via openings 619A, B, C inclusive of filling the via openings 619A, B, C with conductive until a substrate having any number of layers is formed. The resultant substrate may be bonded to a component as shown with respect to FIG. 1 herein. Although illustrated with respect to package build up layers, in some embodiments, such build up is provided using bulk dielectric deposition, patterning and etch techniques, and the like.

FIG. 7A illustrates an example capacitor structure 700 including a build up layer 701 having via openings 703 therein in analogy to FIG. 6B above. Although illustrated with respect to forming capacitor structures on build up layer 701 or a package substrate, as discussed, the capacitor structures herein may be formed over any suitable substrate such as a silicon wafer substrate (including devices formed therein), a motherboard or platform substrate, or the like. Openings 703 may be formed using any suitable technique or techniques such as drilling through build up layer 701, patterning and etch techniques, or the like.

FIG. 7B illustrates an example capacitor structure 702 similar to capacitor structure 700, after the formation bottom electrode 705 and pad 797. Bottom electrode 705 and pad 797 may be formed using any suitable technique or techniques such as depositing a metal layer on build up layer 701 and in openings 703 and patterning the metal layer using lithography and etch techniques. In some embodiments, bottom electrode 705 and pad 797 are formed using semi-additive processing.

FIG. 7C illustrates an example capacitor structure 704 similar to capacitor structure 702, after the formation of a material stack 707. Multilayer capacitor material stack 707 may include any of multilayer capacitor material stacks 123, 323, 333, with multilayer capacitor material stack 123 being illustrated for the sake of clarity. As shown, in some embodiments, multilayer capacitor material stack 707 includes bulk material layers (i.e., not yet patterned layers) of high density metal layer 252, conductive noble metal oxide layer 251, TMO dielectric layer 203, conductive noble metal oxide layer 261, and high density metal layer 262. In some embodiments, multilayer capacitor material stack 707 includes bulk material layers of high density metal layer 353, TMO dielectric layer 203, conductive noble metal oxide layer 261, and high density metal layer 262 (refer to FIG. 3A). In some embodiments, multilayer capacitor material stack 707 includes bulk material layers of high density metal layer 252, conductive noble metal oxide layer 251, TMO dielectric layer 203, and high density metal layer 363 (refer to FIG. 3B). The layers of multilayer capacitor material stack 707 may be formed using any suitable technique or techniques inclusive of sputtering, co-reactive sputtering, plating techniques, atomic layer deposition, chemical vapor deposition, or the like.

FIG. 7D illustrates an example capacitor structure 706 similar to capacitor structure 704, after the formation of a conductive layer 709. Conductive layer 709 may be formed using any suitable technique or techniques such as electroplating or deposition techniques. Conductive layer 709 may include any suitable metal material for a conductive electrode or layer such as copper or the like.

FIG. 7E illustrates an example capacitor structure 708 similar to capacitor structure 706, after the formation of a photoresist pattern 711 over conductive layer 709. For example, a bulk photoresist material may be deposited and pattered using photolithography techniques to provide photoresist pattern 711. Although discussed with respect to photolithography techniques any patterning techniques may be employed.

FIG. 7F illustrates an example capacitor structure 710 similar to capacitor structure 708, after the patterning of conductive layer 709 and material stack 707 (inclusive of any material stack discussed with respect to FIG. 7C or elsewhere herein) to form a capacitor 799 that includes conductive layer 709 (formed into a top electrode or top electrode layer), bottom electrode 705 and remaining portions of material stack 707 such that capacitor 699 includes a TMO dielectric layer between first and second electrodes, one or both of which includes a conductive noble metal oxide on the TMO dielectric layer and a high density metal layer on the conductive noble metal oxide as discussed herein.

FIG. 7G illustrates an example capacitor structure 712 similar to capacitor structure 710, after the removal of photoresist pattern 711 and after the formation of a solder resist layer 713 having via openings 715. For example, solder resist layer 713 may be laminated, on exposed surfaces of bottom electrode layer 705, conductive layer 709, build-up layer 701, material stack 707, and pad 797, and subsequently patterned to form via openings 715 that expose a surface of the bottom electrode layer 705, a surface of the conductive layer 709, and a surface of the pad 797.

FIG. 7H illustrates an example capacitor structure 714 similar to capacitor structure 712, after formation of a surface finish 717 on the exposed surfaces of bottom electrode layer 705, conductive layer 709, and pad 797 and within via opening 715. Surface finish 717 may be formed using any suitable technique or techniques known in the art.

FIG. 7I illustrates an example capacitor structure 716 similar to capacitor structure 714, after the formation of interconnects 719. Although illustrated with respect to bumps, interconnects 719 may be any suitable interconnect structures such as pillars, posts, or the like. Such interconnects 719 may be formed using any suitable technique or techniques known in the art.

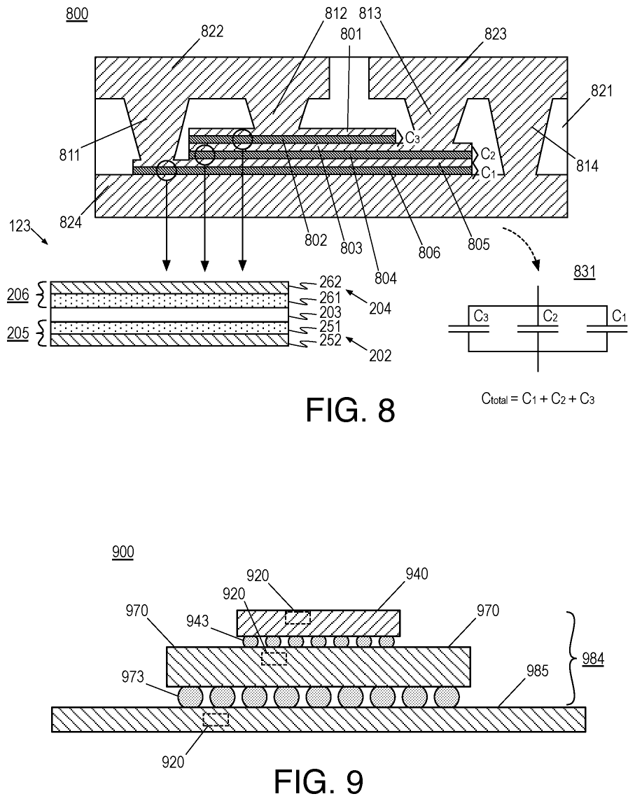

FIG. 8 is an illustration of an example multi-layer capacitor circuit 800, arranged in accordance with at least some implementations of the present disclosure. Notably, the thin film capacitor structures discussed herein may be formed as a single capacitor layer or with multiple layers for increased capacitance density. As shown, multi-layer thin film capacitor circuit 800 provides circuitry, as shown with respect to circuit diagram 831 such that a total capacitance (Cₜₒₜₐₗ) provided by multi-layer thin film capacitor circuit 800 is a sum of capacitances (Cₜₒₜₐₗ=C₁+C₂+C₃) of each layer of multi-layer thin film capacitor circuit 800.

Also as shown, multi-layer thin film capacitor circuit 800 comprises three multilayer capacitor material stacks 802, 804, 806, which may have any characteristics as discussed herein with respect to multilayer capacitor material stacks 123, 323, 333 with multilayer capacitor material stack 123 being illustrated for the sake of clarity. As shown, in some embodiments, the multilayer capacitor material stack high density metal layer 252, conductive noble metal oxide layer 251, TMO dielectric layer 203, conductive noble metal oxide layer 261, and high density metal layer 262. In some embodiments, the multilayer capacitor material stack includes bulk material layers of high density metal layer 353, TMO dielectric layer 203, conductive noble metal oxide layer 261, and high density metal layer 262 (refer to FIG. 3A). In some embodiments, the multilayer capacitor material stack includes bulk material layers of high density metal layer 252, conductive noble metal oxide layer 251, TMO dielectric layer 203, and high density metal layer 363 (refer to FIG. 3B).

Furthermore, multi-layer thin film capacitor circuit 800 includes metal layers or electrodes 801, 803, 805 to provide coupling circuitry for multi-layer thin film capacitor circuit 800. Such metal layers or electrodes 801, 803, 805 are coupled to vias 812, 813, 811, respectively and metal interconnects 822, 823, 824 (optionally with via 814) interconnect multilayer capacitor material stacks 802, 804, 806 to form capacitors C₁, C₂, and C₃ of multi-layer thin film capacitor circuit 800. Such components may be embedded within a dielectric or build up layer 821, as shown. Although illustrated with respect to three multilayer capacitor material stacks 802, 804, 806, any number may be employed. Furthermore, multilayer capacitor material stacks 802, 804, 806 may include the same material systems or they may be different.

FIG. 9 is an illustration of a cross-sectional side view of a packaged system 900, arranged in accordance with at least some implementations of the present disclosure. As shown, packaged system 900 includes a semiconductor package 984 mounted to a board 985 (e.g., a PCB, motherboard, platform, etc.). Furthermore, semiconductor package 984 includes a package substrate 970 and a component 940 such as one or more dies, one or more die stacks mounted to package substrate 970. In some embodiments, package 984 comprises components that are similar to or the same as the components described above in connection with semiconductor package 100. In some embodiments, package 984 includes a package substrate 970 that includes one or more thin film capacitors 920. Thin film capacitors 920 may include any characteristics, material stacks, and so on discussed elsewhere herein. Furthermore, component 940 as mounted to package substrate 970 may include one or more thin film capacitors 920. As shown, component 940 may be electrically coupled to package substrate 970 using interconnects 943.

Furthermore, semiconductor package 984 may be electrically coupled to a board 985 via interconnects 973 such as balls (as shown), pillars, or any other suitable interconnect architecture, such as wire bonding, ball grid array, pin grid array, land grid array, etc. Also as shown, board 985 may include one or more thin film capacitors 920. As shown in FIG. 9, thin film capacitors 920 may be employed in one, some, or all of board 985, package substrate 970, and component 940. Thereby, the discussed thin film capacitor structures may be advantageously used at any level in a system architecture for improved performance.

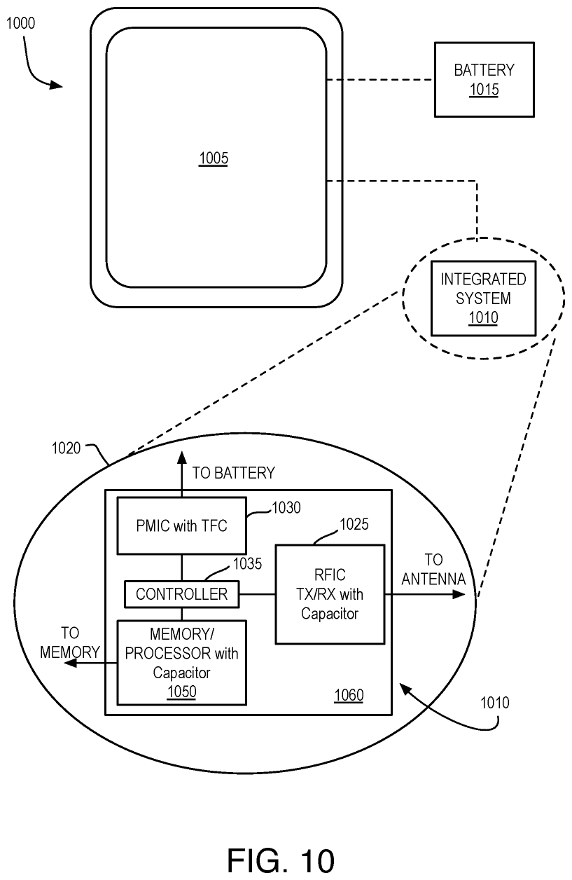

FIG. 10 is an illustrative diagram of a mobile computing platform 1000 employing a device having a capacitor, arranged in accordance with at least some implementations of the present disclosure. Any die or device having a thin film capacitor inclusive of any components, materials, or characteristics discussed herein may be implemented by any component of mobile computing platform 1000. Mobile computing platform 1000 may be any portable device configured for each of electronic data display, electronic data processing, wireless electronic data transmission, or the like. For example, mobile computing platform 1000 may be any of a tablet, a smart phone, a netbook, a laptop computer, etc. and may include a display screen 1005, which in the exemplary embodiment is a touchscreen (e.g., capacitive, inductive, resistive, etc. touchscreen), a chip-level (system on chip—SoC) or package-level integrated system 1010, and a battery 1015. Battery 1015 may include any suitable device for providing electrical power such as a device consisting of one or more electrochemical cells and electrodes to couple to an outside device. Mobile computing platform 1000 may further include a power supply to convert a source power from a source voltage to one or more voltages employed by other devices of mobile computing platform 1000.

Integrated system 1010 is further illustrated in the expanded view 1020. In the exemplary embodiment, packaged device 1050 (labeled “Memory/Processor” in FIG. 10) includes at least one memory chip (e.g., RAM), and/or at least one processor chip (e.g., a microprocessor, a multi-core microprocessor, or graphics processor, or the like). In an embodiment, the package device 1050 is a microprocessor including an SRAM cache memory. As shown, device 1050 may employ a die or device having any thin film capacitor structures and/or related characteristics discussed herein. Packaged device 1050 may be further coupled to (e.g., communicatively coupled to) a board, a substrate, or an interposer 1060 along with, one or more of a power management integrated circuit (PMIC) 1030, RF (wireless) integrated circuit (RFIC) 1025 including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In general, packaged device 1050 may also be coupled to (e.g., communicatively coupled to) display screen 1005. As shown, one or both of PMIC 1030 and RFIC 1025 may employ a die or device having any thin film capacitor structures and/or related characteristics discussed herein.

Functionally, PMIC 1030 may perform battery power regulation, DC-to-DC conversion, etc., and so has an input coupled to battery 1015 and with an output providing a current supply to other functional modules. In an embodiment, PMIC 1030 may perform high voltage operations. As further illustrated, in the exemplary embodiment, RFIC 1025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, SG, and beyond. In alternative implementations, each of these board-level modules may be integrated onto separate ICs coupled to the package substrate of packaged device 1050 or within a single IC (SoC) coupled to the package substrate of the packaged device 1050.

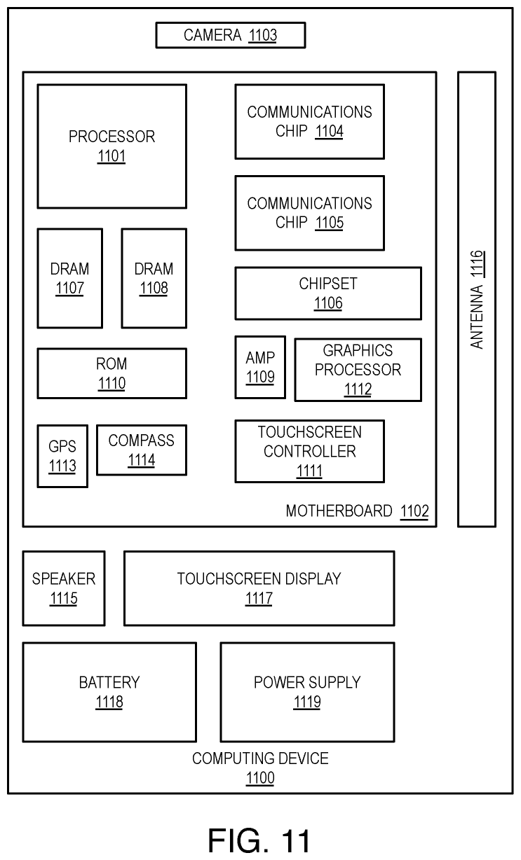

FIG. 11 is a functional block diagram of a computing device 1100, arranged in accordance with at least some implementations of the present disclosure. Computing device 1100 may be found inside platform 1000, for example, and further includes a motherboard 1102 hosting a number of components, such as but not limited to a processor 1101 (e.g., an applications processor) and one or more communications chips 1104, 1105. Processor 1101 may be physically and/or electrically coupled to motherboard 1102. In some examples, processor 1101 includes an integrated circuit die packaged within the processor 1101. In general, the term “processor” may refer to any device or portion of a device that processes electronic data from registers and/or memory to transform that electronic data into other electronic data that may be stored in registers and/or memory. Any one or more device or component of computing device 1100 may include a die or device having any thin film capacitor structures and/or related characteristics discussed herein as discussed herein.

In various examples, one or more communication chips 1104, 1105 may also be physically and/or electrically coupled to the motherboard 1102. In further implementations, communication chips 1104 may be part of processor 1101. Depending on its applications, computing device 1100 may include other components that may or may not be physically and electrically coupled to motherboard 1102. These other components may include, but are not limited to, volatile memory (e.g., DRAM) 1107, 1108, non-volatile memory (e.g., ROM) 1110, a graphics processor 1112, flash memory, global positioning system (GPS) device 1113, compass 1114, a chipset 1106, an antenna 1116, a power amplifier 1109, a touchscreen controller 1111, a touchscreen display 1117, a speaker 1115, a camera 1103, a battery 1118, and a power supply 1119, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like.

Communication chips 1104, 1105 may enable wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1104, 1105 may implement any of a number of wireless standards or protocols, including but not limited to those described elsewhere herein. As discussed, computing device 1100 may include a plurality of communication chips 1104, 1105. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. Furthermore, power supply 1119 may convert a source power from a source voltage to one or more voltages employed by other devices of mobile computing platform 1000. In some embodiments, power supply 1119 converts an AC power to DC power. In some embodiments, power supply 1119 converts an DC power to DC power at one or more different (lower) voltages. In some embodiments, multiple power supplies are staged to convert from AC to DC and then from DC at a higher voltage to DC at a lower voltage as specified by components of computing device 1100.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In one or more first embodiments, a capacitor comprises a first electrode comprising a multilayer stack, a second electrode, and a dielectric layer between the first and second electrodes, wherein the dielectric layer comprises a transition metal and oxygen, and wherein the multilayer material stack comprises a first layer on the dielectric layer and a second layer on the first layer, the first layer comprising a noble metal and oxygen, and the second layer comprising tungsten.

In one or more second embodiments, further to the first embodiments, the transition metal comprises titanium, the noble metal comprises ruthenium, and the second layer comprises substantially pure tungsten.

In one or more third embodiments, further to the first or second embodiments, the second layer comprises not less than 99% tungsten.

In one or more fourth embodiments, further to the first through third embodiments, the second electrode comprises a third layer on the dielectric layer, the third layer comprising substantially pure iridium.

In one or more fifth embodiments, further to the first through fourth embodiments, the transition metal comprises titanium, the noble metal comprises iridium, and the second layer comprises substantially pure tungsten.

In one or more sixth embodiments, further to the first through fifth embodiments, the second electrode comprises a third layer on the dielectric layer, the third layer comprising substantially pure iridium.

In one or more seventh embodiments, further to the first through sixth embodiments, the second electrode comprises a second multilayer stack comprising a third layer on the dielectric layer and a fourth layer on the first layer, the third layer comprising oxygen and the noble metal or a second noble metal, and the fourth layer comprising tungsten, iridium, gold, platinum, osmium, or tantalum.

In one or more eighth embodiments, further to the first through seventh embodiments, the transition metal comprises titanium, the third layer comprises the noble metal and oxygen, the noble metal comprises ruthenium or iridium, and the fourth layer comprises tungsten or iridium.

In one or more ninth embodiments, further to the first through eighth embodiments, the noble metal comprises ruthenium.

In one or more tenth embodiments, further to the first through ninth embodiments, the noble metal comprises one of ruthenium, rhodium, palladium, silver, osmium, iridium, platinum, or gold.

In one or more eleventh embodiments, further to the first through tenth embodiments, the transition metal comprises one of hafnium, aluminum, zirconium, or titanium.

In one or more twelfth embodiments, a capacitor comprises a first electrode, a second electrode, and a dielectric layer between the first and second electrodes, wherein the dielectric layer comprises a transition metal and oxygen, the first electrode comprises a first layer on the dielectric layer and a second layer on the first layer, and the second electrode comprises a third layer on the dielectric layer and a fourth layer on the third layer, the first layer comprising a noble metal and oxygen, the third layer comprising oxygen and the noble metal or a second noble metal, the second layer comprising a metal having a density of not less than 16 g/cc, and the fourth layer comprising the metal or a second metal having a density of not less than 16 g/cc.

In one or more thirteenth embodiments, further to the twelfth embodiments, the transition metal comprises titanium, and the noble metal comprises one of ruthenium or iridium.

In one or more fourteenth embodiments, further to the twelfth or thirteenth embodiments, the metal comprises one of tungsten, iridium, gold, platinum, osmium, or tantalum.

In one or more fifteenth embodiments, further to the twelfth through fourteenth embodiments, the metal comprises tungsten and the second metal comprises one of iridium, gold, platinum, osmium, or tantalum.

In one or more sixteenth embodiments, a system comprises a power supply, an integrated circuit die over a package substrate and coupled to the power supply, and a capacitor in one of the integrated circuit die or the package substrate, the capacitor in accordance with any of the first through fifteenth embodiments.

In one or more seventeenth embodiments, a system comprises a power supply, an integrated circuit die over a package substrate and coupled to the power supply, and a capacitor in one of the integrated circuit die or the package substrate, the capacitor comprising a dielectric layer comprising a transition metal and oxygen between first and second electrodes, wherein the first electrode comprises a first layer on the dielectric layer and a second layer on the first layer, the first layer comprising a noble metal and oxygen, and the second layer comprising tungsten.

In one or more eighteenth embodiments, further to the seventeenth embodiments, the transition metal comprises titanium, the noble metal comprises ruthenium or iridium, and the second layer comprises substantially pure tungsten.

In one or more nineteenth embodiments, further to the seventeenth or eighteenth embodiments, the second electrode comprises a third layer on the dielectric layer, the third layer comprising iridium.

In one or more twentieth embodiments, further to the seventeenth through nineteenth embodiments, the second electrode comprises a third layer on the dielectric layer and a fourth layer on the third layer, the third layer comprising oxygen and the noble metal or a second noble metal, and the fourth layer comprising tungsten, iridium, gold, platinum, osmium, or tantalum.

In one or more twenty-first embodiments, further to the seventeenth through twentieth embodiments, the transition metal comprises titanium, the third layer comprises the noble metal and oxygen, the noble metal comprises ruthenium or iridium, the second layer comprises tungsten, and the fourth layer comprises tungsten or iridium.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A capacitor, comprising
a first electrode comprising a multilayer stack;
a second electrode; and
a dielectric layer between the first and second electrodes, wherein the dielectric layer comprises a transition metal and oxygen, and wherein the multilayer material stack comprises a first layer on the dielectric layer and a second layer on the first layer, the first layer comprising a noble metal and oxygen, and the second layer comprising tungsten.

2. The capacitor of claim 1, wherein the transition metal comprises titanium, the noble metal comprises ruthenium, and the second layer comprises substantially pure tungsten.

3. The capacitor of claim 2, wherein the second layer comprises not less than 99% tungsten.

4. The capacitor of claim 2, wherein the second electrode comprises a third layer on the dielectric layer, the third layer comprising substantially pure iridium.

5. The capacitor of claim 1, wherein the transition metal comprises titanium, the noble metal comprises iridium, and the second layer comprises substantially pure tungsten.

6. The capacitor of claim 5, wherein the second electrode comprises a third layer on the dielectric layer, the third layer comprising substantially pure iridium.

7. The capacitor of claim 1, wherein the second electrode comprises a second multilayer stack comprising a third layer on the dielectric layer and a fourth layer on the first layer, the third layer comprising oxygen and the noble metal or a second noble metal, and the fourth layer comprising tungsten, iridium, gold, platinum, osmium, or tantalum.

8. The capacitor of claim 7, wherein the transition metal comprises titanium, the third layer comprises the noble metal and oxygen, the noble metal comprises ruthenium or iridium, and the fourth layer comprises tungsten or iridium.

9. The capacitor of claim 8, wherein the noble metal comprises ruthenium.

10. The capacitor of claim 1, wherein the noble metal comprises one of ruthenium, rhodium, palladium, silver, osmium, iridium, platinum, or gold.

11. The capacitor of claim 1, wherein the transition metal comprises one of hafnium, aluminum, zirconium, or titanium.

12. A capacitor, comprising
a first electrode;
a second electrode; and
a dielectric layer between the first and second electrodes, wherein the dielectric layer comprises a transition metal and oxygen, the first electrode comprises a first layer on the dielectric layer and a second layer on the first layer, and the second electrode comprises a third layer on the dielectric layer and a fourth layer on the third layer, the first layer comprising a noble metal and oxygen, the third layer comprising oxygen and the noble metal or a second noble metal, the second layer comprising a metal having a density of not less than 16 g/cc, and the fourth layer comprising the metal or a second metal having a density of not less than 16 g/cc.

13. The capacitor of claim 12, wherein the transition metal comprises titanium, and the noble metal comprises one of ruthenium or iridium.

14. The capacitor of claim 12, wherein the metal comprises one of tungsten, iridium, gold, platinum, osmium, or tantalum.

15. The capacitor of claim 12, wherein the metal comprises tungsten and the second metal comprises one of iridium, gold, platinum, osmium, or tantalum.

16. A system comprising:
a power supply;
an integrated circuit die over a package substrate and coupled to the power supply; and
a capacitor in one of the integrated circuit die or the package substrate, the capacitor comprising a dielectric layer comprising a transition metal and oxygen between first and second electrodes, wherein the first electrode comprises a first layer on the dielectric layer and a second layer on the first layer, the first layer comprising a noble metal and oxygen, and the second layer comprising tungsten.

17. The system of claim 16, wherein the transition metal comprises titanium, the noble metal comprises ruthenium or iridium, and the second layer comprises substantially pure tungsten.

18. The system of claim 17, wherein the second electrode comprises a third layer on the dielectric layer, the third layer comprising iridium.

19. The system of claim 16, wherein the second electrode comprises a third layer on the dielectric layer and a fourth layer on the third layer, the third layer comprising oxygen and the noble metal or a second noble metal, and the fourth layer comprising tungsten, iridium, gold, platinum, osmium, or tantalum.

20. The system of claim 19, wherein the transition metal comprises titanium, the third layer comprises the noble metal and oxygen, the noble metal comprises ruthenium or iridium, the second layer comprises tungsten, and the fourth layer comprises tungsten or iridium.
